(19) United States
(12) Patent Application Publication
(10) Pub. No.: US 2026/0047105 A1
(43) Pub. Date: Feb. 12, 2026

(54) RESISTIVE RANDOM ACCESS MEMORY AND MANUFACTURING METHOD THEREOF

(71) Applicant: Taiwan Semiconductor Manufacturing Company, Ltd., Hsinchu (TW)

(72) Inventors: Ching-Pei HSIEH, Hsinchu (TW); I-Ching CHEN, Hsinchu (TW); Yung-Hsieh LIN, Hsinchu (TW); Ding-I LIU, Hsinchu (TW)

(73) Assignee: Taiwan Semiconductor Manufacturing Company, Ltd., Hsinchu (TW)

(21) Appl. No.: 18/796,085

(22) Filed: Aug. 6, 2024

(51) Int. Cl. H10B 63/00; H10N 70/00

(52) U.S. Cl. CPC H10B 63/20; H10N 70/063

(57) ABSTRACT

A method of manufacturing a resistive random access memory includes the following steps. An interlayer dielectric layer is formed on a semiconductor substrate. A first conductive material layer is formed in a through hole of the interlayer dielectric layer. At least one interface layer is formed in the through hole. The interface layer covers a bottom surface of the first conductive material layer and exposes a portion of a side surface of the first conductive material layer. A resistive material layer is formed in the through hole and covers the interface layer and the first conductive material layer. A second conductive material layer is formed in the through hole and covers the resistive material layer. A planarization is performed on the first conductive material layer, the resistive material layer and the second conductive material layer to form an embedded resistive random access memory in the through hole.

### BACKGROUND

In recent years, unconventional nonvolatile memory (NVM) devices, such as ferroelectric random access memory (FRAM) devices, phase-change random access memory (PRAM) devices, and resistive random access memory (RRAM) devices, have emerged. In particular, RRAM devices, which exhibit a switching behavior between a high resistance state (HRS) and a low resistance state (LRS), have various advantages over conventional NVM devices. Such advantages include, for example, compatible fabrication steps with current complementary-metal-oxide-semiconductor (CMOS) technologies, low-cost fabrication, a compact structure, flexible scalability, fast switching, high integration density, and so on. Moreover, RRAM implementations could be very useful hardware for running artificial intelligence (AI) and machine learning (ML) applications due to the increasing computational demands necessary for many improvements in AI and ML.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1G are schematic diagrams of a method of manufacturing a resistive random access memory according to an embodiment of the present disclosure.

FIGS. 2A to 2G are schematic diagrams of a method of manufacturing a resistive random access memory according to another embodiment of the present disclosure.

FIG. 3 is a schematic diagram of a resistive random access memory according to another embodiment of the present disclosure.

FIG. 4 is a schematic diagram of a resistive random access memory according to another embodiment of the present disclosure.

FIGS. 5 and 6 respectively are schematic diagrams of a planar RRAM structure and an embedded RRAM structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

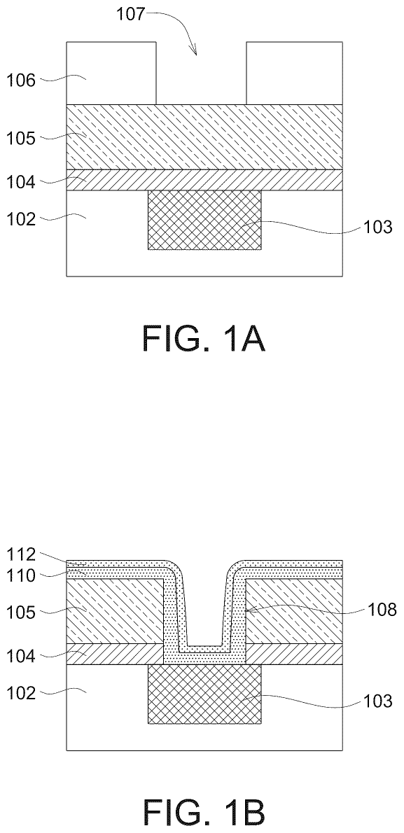

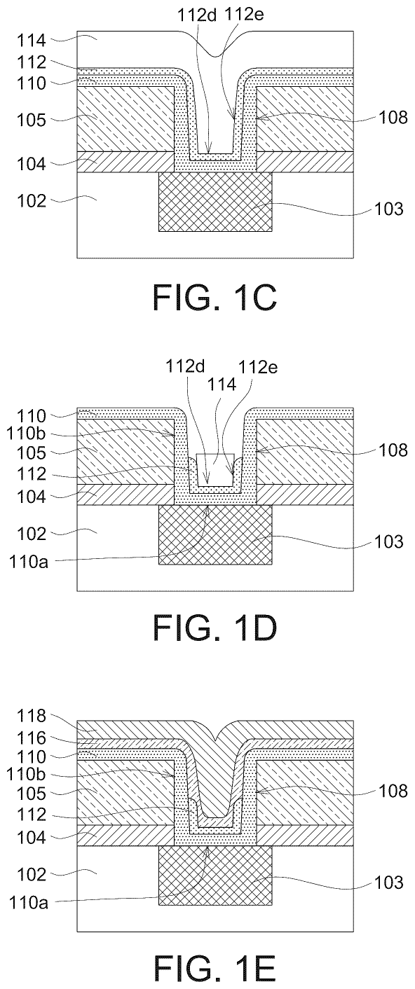

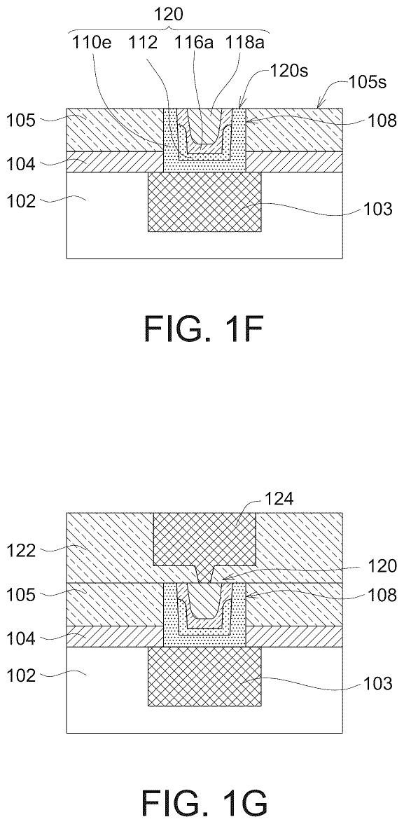

FIGS. 1A to 1G are schematic diagrams of a method of manufacturing a resistive random access memory (RRAM) 120 according to an embodiment of the present disclosure. Referring to FIG. 1A, an interlayer dielectric layer 105 is formed on a semiconductor substrate 102. The interlayer dielectric layer 105 is subjected to a patterning process, and the interlayer dielectric layer 105 is partially etched to form a through hole 108 penetrating the interlayer dielectric layer 105. For example, a patterned photoresist layer 106 is formed on the interlayer dielectric layer 105 to expose part of the interlayer dielectric layer 105 in an opening 107 of the patterned photoresist layer 106. Dry etching or wet etching is performed to form a through hole 108 in the interlayer dielectric layer 105. In addition, an insulating material layer 104 (such as silicon carbide or silicon oxide) can be disposed between the interlayer dielectric layer 105 and the semiconductor substrate 102 to serve as an etching stop layer.

In one embodiment, the insulating material layer 104 and the interlayer dielectric layer 105 can be formed on the semiconductor substrate 102 by a deposition or spin coating process to cover the upper surface of the semiconductor substrate 102. Then, an etching process (for example, a dry photoresist etching process) is performed to remove a portion of the interlayer dielectric layer 105 and a portion of the insulating material layer 104 located above the semiconductor substrate 102 so as to form at least one (or a plurality of) through hole 108. The through hole 108 extends downward from the upper surface of the interlayer dielectric layer 105, and a portion of the semiconductor substrate 102 is exposed in the through hole 108. In one embodiment, the through hole 108 may be a rectangular opening, a trapezoidal opening, or a stepped opening with different inner diameters.

In one embodiment, the semiconductor substrate 102 may be a silicon substrate, silicon on an insulating layer, or other semiconductor materials. The interlayer dielectric layer 105 may be a single material or a dielectric layer composed of multiple materials covering the semiconductor substrate 102 (for example, a silicon oxide layer, a silicon nitride layer, silicon nitride carbide, a low dielectric coefficient (LK) material layer, ultra-low dielectric coefficient (ULK) material layer or any combination of the above materials). In addition, the semiconductor substrate 102 further includes at least one first patterned conductive layer 103. Through the etching and perforation process, a portion of the first patterned conductive layer 103 (e.g., metal wires or conductive plugs) located in the semiconductor substrate 102 can be exposed at the bottom of the through hole 108 (as shown in FIG. 1B). The material of the first patterned conductive layer 103 may be copper or tungsten.

Referring to FIG. 1B, a first conductive material layer 110 is formed in the through hole 108 of the interlayer dielectric layer 105. Next, at least one interface layer 112 is formed in the through hole 108. The interface layer 112 covers the first conductive material layer 110, and the interface layer 112 and the first conductive material layer 110 conformally cover the upper surface of the interlayer dielectric layer 105 and are recessed in the through hole 108.

In one embodiment, the first conductive material layer 110 and at least one interface layer 112 can be formed on the interlayer dielectric layer 105 through a deposition process. The deposition process is, for example, an atomic layer deposition (ALD) process, an epitaxial growth process, a low pressure chemical vapor deposition (LPCVD) process and/or a plasma enhanced chemical vapor deposition (PECVD) process. The first conductive material layer 110 may be electrically connected to the first patterned conductive layer 103 below the first conductive material layer 110. The first conductive material layer 110 may serve as a lower electrode layer 110e (see FIG. 1F). The lower electrode layer 110e includes titanium, tantalum, titanium nitride, tantalum nitride or other metal materials.

The interface layer 112 may be a dielectric layer composed of a single material or multiple materials, such as silicon nitride, silicon carbide, silicon oxynitride or a combination of the above materials. The shape of the interface layer 112 can be changed by etching back. Through etching back, the height of the interface layer 112 can be smaller than the height of the through hole 108, about half or a quarter of the height of the through hole 108. In one embodiment, the interface layer 112 is, for example, U-shaped to enhance the insulation between the first conductive material layer 110 and the second conductive material layer 118.

Referring to FIG. 1C, a mask layer 114 is formed in the through hole 108. The mask layer 114 covers the bottom surface 112d of the interface layer 112 and at least a portion of the side surface 112e. The mask layer 114 is used to define the feature size of the interface layer 112. In one embodiment, a patterning process is performed on the mask layer 114 and the mask layer 114 is partially etched, so that the mask layer 114 exposes at least a portion of the side surface 112e of the interface layer 112. Next, referring to FIG. 1D, the interface layer 112 is partially etched back to remove the portion not covered by the mask layer 114, so that the interface layer 112 covers a bottom surface 110a of the first conductive material layer 110 and exposes a portion of a side surface 110b of the first conductive material layer 110.

Referring to FIG. 1E, a resistive material layer 116 is formed in the through hole 108. The resistive material layer 116 covers the interface layer 112 and the side surface 110b of the first conductive material layer 110. In one embodiment, the resistive material layer 116 can be formed comprehensively on the interlayer dielectric layer 105 through a deposition process, and the resistive material layer 116 is recessed in the through hole 108. The deposition process is, for example, an atomic layer deposition (ALD) process, an epitaxial growth process, a low pressure chemical vapor deposition (LPCVD) process and/or a plasma enhanced chemical vapor deposition (PECVD) process.

The resistive material layer 116 is, for example, a transition metal oxide, which may be composed of a metal oxide compound represented by the chemical formula MOx, where M is selected from the group consisting of tungsten (W), titanium (Ti), titanium nitride (TiN), Aluminum (Al), Nickel (Ni), Copper (Cu), Zirconium, Hafnium (Hf), Niobium (Nb), Tantalum (Ta), or any combination of these metals. For example, the resistive material layer 116 may be Hafnium Oxide (HfOx), Zirconium Oxide (ZrOx), Aluminum Oxide (AlOx), Nickel Oxide (NiOx), tantalum oxide Tantalum Oxide (TaOx), titanium oxide (Titanium Oxide, TiOx) or any combination of the above materials.

Referring to FIG. 1E, a second conductive material layer 118 is formed in the through hole 108, and the second conductive material layer 118 covers the resistive material layer 116. In one embodiment, the second conductive material layer 118 can be formed comprehensively on the resistive material layer 116 through a deposition process, and the second conductive material layer 118 is recessed in the through hole 108. The deposition process is, for example, an atomic layer deposition (ALD) process, an epitaxial growth process, a low pressure chemical vapor deposition (LPCVD) process, and/or a plasma enhanced chemical vapor deposition (PECVD) process.

The second conductive material layer 118 may be the same as or different from the first conductive material layer 110. The second conductive material layer 118 can serve as an upper electrode layer 118a (see FIG. 1F). The upper electrode layer 118a includes titanium, tantalum, titanium nitride, tantalum nitride or other metal materials. In addition, the upper electrode layer 118a may be a work function layer, selected from a group consisting of cobalt (Co), nickel (Ni), Plumbum (Pb), gold (Au), rhenium (Re), iridium (Ir), titanium (Ti), Hafnium (Hf), platinum (Pt), ruthenium (Ru), aluminum (Al) and any combination of the above materials.

Referring to FIG. 1F, a planarization process is performed on the first conductive material layer 110, the resistive material layer 116 and the second conductive material layer 118 to form an embedded resistive random access memory (RRAM) 120 in the through hole 108. In one embodiment, a portion of the first conductive material layer 110, the resistive material layer 116, and the second conductive material layer 118 located on the upper surface 105s of the interlayer dielectric layer 105 are removed by chemical polishing or mechanical polishing, leaving only the portions of the first conductive material layer 110, the resistive material layer 116 and the second conductive material layer 118 in the through hole 108. After the planarization process, the first conductive material layer 110, the resistive material layer 116 and the second conductive material layer 118 can be used as the lower electrode layer 110e and the resistance conversion layer 116a and the upper electrode layer 118a of the embedded resistive random access memory (RRAM) 120 respectively, and the polished upper surfaces 120s of the first conductive material layer 110, the resistive material layer 116 and the second conductive material layer 118 are at the same height, or the polished upper surfaces 120s of the first conductive material layer 110, the resistive material layer 116 and the second conductive material layer 118 are coplanar with the upper surface 105s of the polished interlayer dielectric layer 105.

Referring to FIG. 1G, a second interlayer dielectric layer 122 is formed on the polished upper surface 105s of the interlayer dielectric layer 105, and a second patterned conductive layer 124 (for example, metal wires or conductive plugs) in the second interlayer dielectric layer 122. The second patterned conductive layer 124 is electrically connected to the upper electrode layer 118a. The material of the second patterned conductive layer 124 may be the same or different material from the first patterned conductive layer 103. The material of the second patterned conductive layer 124 may be copper or tungsten.

The resistive random access memory (RRAM) is used to be applied a pulse voltage to the transition metal oxide to generate a resistance difference as a basis for interpreting information storage states such as “0” and “1”. RRAM is a type of non-volatile (NV) random-access (RAM) memory that works by changing the resistance across a dielectric solid-state material, often referred to as a memristor. RRAM involves generating defects in a thin oxide layer, known as oxygen vacancies (oxide bond locations where the oxygen has been removed), which can subsequently charge and drift under an electric field. The motion of oxygen ions and vacancies in the oxide would be analogous to the motion of electrons and holes in a semiconductor. One major advantage of RRAM over other NVRAM technologies is the ability to scale below 10 nm. However, the size of traditional RRAM is difficult to reduce due to the planar type of the bottom electrode and top electrode.

In this embodiment, the size of the embedded resistive random access memory (RRAM) 120 is determined by the aperture of the through hole 108. The aperture of the through hole 108 is approximately less than 10 nm or 5 nm to reduce planar dimensions (such as width and length) of the embedded resistive random access memory (RRAM) 120. In addition, the first conductive material layer 110, the resistive material layer 116 and the second conductive material layer 118 form a similar U-shaped or rectangular structure in the through hole 108, which can increase the electric field per unit area. In one embodiment, after an external bias voltage is applied to the upper electrode layer 118a and the lower electrode layer 110e of the RRAM structure, an electric field will be formed around the resistance conversion layer 116a. At this time, some oxygen atoms in the resistance conversion layer 116a will leave their lattice positions, and stored in the oxygen atom storage layer, thus forming oxygen vacancies in the resistance conversion layer 116a. These oxygen vacancies will form conductive filaments, converting the resistive random access memory into a low-resistance state, the greater the electric field, the faster the conductive filaments are formed, that is, the faster the switching speed between the high resistance state and the low resistance state of the resistive random access memory (RRAM) 120 is. Therefore, in this embodiment, the shape of the lower electrode layer 110e is designed to be a U-shaped profile. The U-shaped lower electrode layer 110e covers the resistance conversion layer 116a and the upper electrode layer 118a. Since the electric field of the U-shaped lower electrode layer 110e is concentrated, the electric field is strong, so the formation speed of the conductive filaments in the resistance conversion layer 116a will be increased, thereby increasing the programming speed of the resistive random access memory (RRAM) 120.

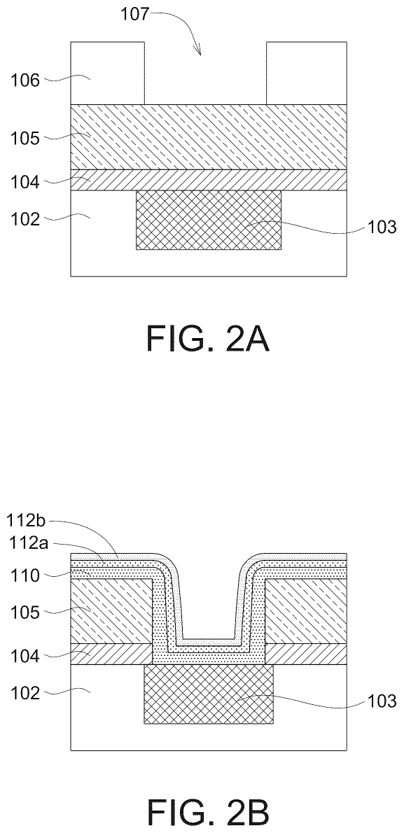

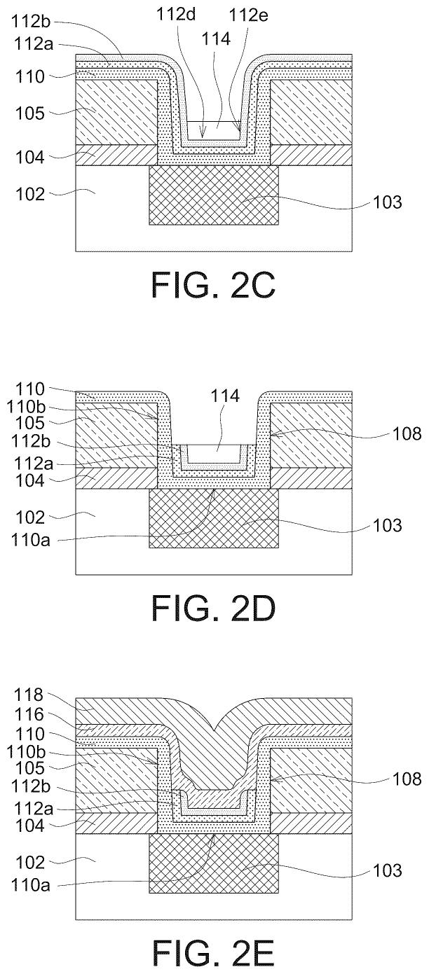

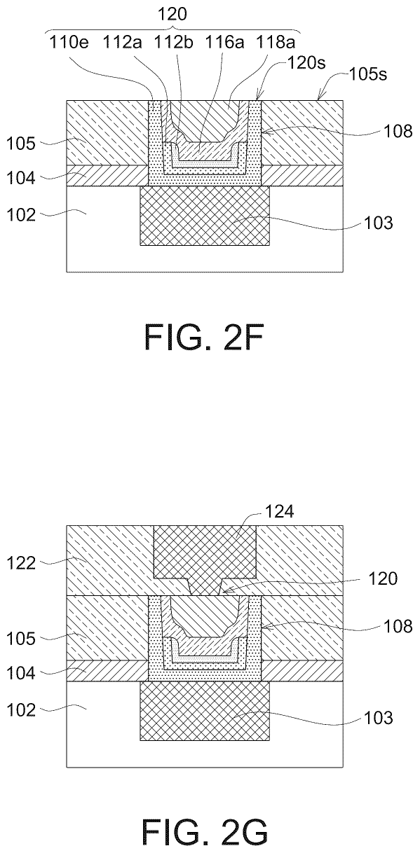

FIGS. 2A to 2G are schematic diagrams of a method of manufacturing a resistive random access memory (RRAM) 120 according to another embodiment of the present disclosure. Referring to FIG. 2A, an interlayer dielectric layer 105 is formed on a semiconductor substrate 102. The interlayer dielectric layer 105 is subjected to a patterning process, and the interlayer dielectric layer 105 is partially etched to form a through hole 108 penetrating the interlayer dielectric layer 105. For example, a patterned photoresist layer 106 is formed on the interlayer dielectric layer 105 to expose part of the interlayer dielectric layer 105 in the opening 107 of the patterned photoresist layer 106. Dry etching or wet etching is performed to form a through hole 108 in the interlayer dielectric layer 105. In addition, an insulating material layer 104 (such as silicon carbide or silicon oxide) can be disposed between the interlayer dielectric layer 105 and the semiconductor substrate 102 to serve as an etching stop layer.

In one embodiment, the through hole 108 extends downward from the upper surface of the interlayer dielectric layer 105, and a portion of the semiconductor substrate 102 is exposed in the through hole 108. In one embodiment, the through hole 108 may be a rectangular opening, a trapezoidal opening, or a stepped opening with different inner diameters.

In addition, through the etching and perforation process, a portion of the first patterned conductive layer 103 (for example, metal wires or conductive plugs) located in the semiconductor substrate 102 can be exposed at the bottom of the through hole 108 (as shown in FIG. 2B). The material of the first patterned conductive layer 103 may be copper or tungsten.

Referring to FIG. 2B, a first conductive material layer 110 is formed in the through hole 108 of the interlayer dielectric layer 105. Then, a first interface layer 112a and a second interface layer 112b are formed in the through hole 108. The first interface layer 112a and the second interface layer 112b cover the first conductive material layer 110, and the first interface layer 112a, the second interface layer 112b and the first conductive material layer 110 conformally cover the upper surface of the interlayer dielectric layer 105 and are recessed in the through hole 108.

In one embodiment, the first conductive material layer 110 may be electrically connected to the first patterned conductive layer 103 below the first conductive material layer 110. The first conductive material layer 110 may serve as a lower electrode layer 110e (as shown in FIG. 2F). The lower electrode layer 110e includes titanium, tantalum, titanium nitride, tantalum nitride or other metal materials.

The first interface layer 112a and the second interface layer 112b may be same or different dielectric layers composed of multiple materials, such as silicon nitride, silicon carbide, silicon oxynitride or a combination of the above materials. The first interface layer 112a and the second interface layer 112b may have same or different thicknesses, the thicker the interface layer, the more protection is provided to the lower electrode layer 110e to prevent the corner areas of the lower electrode layer 110e from being damaged by static electricity accumulation.

In some embodiments, the shapes of the interface layers 112a and 112b can be changed through etching back (refer to FIGS. 2E, 3 and 4). Through etching back, the height of the interface layers 112a and 112b can be smaller than the height of the through hole 108, about half or a quarter of the height of the through hole 108. In one embodiment, the first interface layer 112a and the second interface layer 112b are, for example, U-shaped or other shapes to enhance the insulation between the first conductive material layer 110 and the second conductive material layer 118.

Referring to FIG. 2C, a mask layer 114 is formed in the through hole 108. The mask layer 114 covers the bottom surface 112d and a portion of the side surface 112e of the second interface layer 112. The mask layer 114 is used to define the feature sizes of the first interface layer 112a and the second interface layer 112b. In one embodiment, a patterning process is performed on the mask layer 114, and the mask layer 114 is partially etched, so that the mask layer 114 exposes a portion of the side surface 112e of the second interface layer 112b. Next, referring to FIG. 2D, partial etching back is performed on the first interface layer 112b and the second interface layer 112b to remove the portions not covered by the mask layer 114 so that the first interface layer 112a and the second interface layer 112b cover a bottom surface 110a of the first conductive material layer 110 and exposes a portion of the side surface 110b of the first conductive material layer 110.

Referring to FIG. 2E, a resistive material layer 116 is formed in the through hole 108. The resistive material layer 116 covers the first and second interface layers 112a and 112b and the side surface 110b of the first conductive material layer 110. In one embodiment, the resistive material layer 116 can be formed comprehensively on the interlayer dielectric layer 105 through a deposition process, and the resistive material layer 116 is recessed in the through hole 108.

The resistive material layer 116 is, for example, a transition metal oxide, which can be composed of a metal oxide compound represented by the chemical formula MOx, where M is selected from the group consisting of tungsten (W), titanium (Ti), titanium nitride (TiN), Aluminum (Al), Nickel (Ni), Copper (Cu), Zirconium, Hafnium (Hf), Niobium (Nb), Tantalum (Ta), or any combination of these metals. For example, the resistive material layer 116 may be Hafnium Oxide (HfOx), Zirconium Oxide (ZrOx), Aluminum Oxide (AlOx), Nickel Oxide (NiOx), tantalum oxide Tantalum Oxide (TaOx), titanium oxide (Titanium Oxide, TiOx) or any combination of the above materials.

Referring to FIG. 2F, a second conductive material layer 118 is formed in the through hole 108, and the second conductive material layer 118 covers the resistive material layer 116. In one embodiment, the second conductive material layer 118 can be formed comprehensively on the resistive material layer 116 through a deposition process, and the second conductive material layer 118 is recessed in the through hole 108.

The second conductive material layer 118 may be the same as or different from the first conductive material layer 110. The second conductive material layer 118 can serve as an upper electrode layer 118a (see FIG. 2F). The upper electrode layer 118a includes titanium, tantalum, titanium nitride, tantalum nitride or other metal materials. In addition, the upper electrode layer 118a may be a work function layer, selected from a group consisting of cobalt (Co), nickel (Ni), Plumbum (Pb), gold (Au), rhenium (Re), iridium (Ir), titanium (Ti), Hafnium (Hf), platinum (Pt), ruthenium (Ru), aluminum (Al) and any combination of the above materials.

Referring to FIG. 2F, a planarization process is performed on the first conductive material layer 110, the resistive material layer 116 and the second conductive material layer 118 to form an embedded resistive random access memory (RRAM) 120 in the through hole 108. In one embodiment, a portion of the first conductive material layer 110, the resistive material layer 116, and the second conductive material layer 118 located on the upper surface 105s of the interlayer dielectric layer 105 are removed by chemical polishing or mechanical polishing, leaving only the portions of the first conductive material layer 110, the resistive material layer 116 and the second conductive material layer 118 in the through hole 108. After the planarization process, the first conductive material layer 110, the resistive material layer 116 and the second conductive material layer 118 can be used as the lower electrode layer 110e and the resistance conversion layer 116a and the upper electrode layer 118a of the embedded resistive random access memory (RRAM) 120 respectively, and the polished upper surfaces 120s of the first conductive material layer 110, the resistive material layer 116 and the second conductive material layer 118 are at the same height, or the polished upper surfaces 120s of the first conductive material layer 110, the resistive material layer 116 and the second conductive material layer 118 are coplanar with the upper surface 105s of the polished interlayer dielectric layer 105.

Referring to FIG. 2G, a second interlayer dielectric layer 122 is formed on the polished upper surface 105s of the interlayer dielectric layer 105, and a second patterned conductive layer 124 (for example, metal wires or conductive plugs) in the second interlayer dielectric layer 122. The second patterned conductive layer 124 is electrically connected to the upper electrode layer 118a. The material of the second patterned conductive layer 124 may be the same or different material from the first patterned conductive layer 103. The material of the second patterned conductive layer 124 may be copper or tungsten.

In this embodiment, the size of the embedded resistive random access memory (RRAM) 120 is determined by the aperture of the through hole 108. The aperture of the through hole 108 is approximately less than 10 nm or 5 nm to reduce planar dimensions (such as width and length) of the embedded resistive random access memory (RRAM) 120. In addition, the first conductive material layer 110, the resistive material layer 116 and the second conductive material layer 118 form a similar U-shaped or rectangular structure in the through hole 108, which can increase the electric field per unit area. In one embodiment, after an external bias voltage is applied to the upper electrode layer 118a and the lower electrode layer 110e of the RRAM structure, an electric field will be formed around the resistance conversion layer 116a. At this time, some oxygen atoms in the resistance conversion layer 116a will leave their lattice positions, and stored in the oxygen atom storage layer, thus forming oxygen vacancies in the resistance conversion layer 116a. These oxygen vacancies will form conductive filaments, converting the resistive random access memory into a low-resistance state, the greater the electric field, the faster the conductive filaments are formed, that is, the faster the switching speed between the high resistance state and the low resistance state of the resistive random access memory (RRAM) 120 is. Therefore, in this embodiment, the shape of the lower electrode layer 110e is designed to be a U-shaped profile. The U-shaped lower electrode layer 110e covers the resistance conversion layer 116a and the upper electrode layer 118a. Since the electric field of the U-shaped lower electrode layer 110e is concentrated, the electric field is strong, so the formation speed of the conductive filaments in the resistance conversion layer 116a will be increased, thereby increasing the programming speed of the resistive random access memory (RRAM) 120.

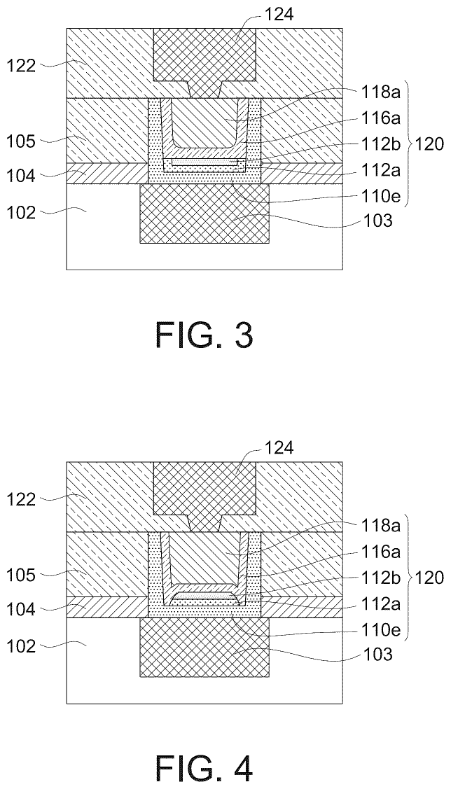

Referring to FIGS. 3 and 4, FIGS. 3 and 4 respectively are schematic diagrams of a resistive random access memory (RRAM) 120 according to an embodiment of the present disclosure. The resistive random access memory (RRAM) 120 is embedded in a through hole 108 and includes a lower electrode layer 110e, at least one interface layer 112a, 112b, a resistance conversion layer 116a and an upper electrode layer 118a. The lower electrode layer 110e is disposed in the through hole 108, and has a U-shaped profile. The interface layers 112a and 112b cover the bottom surface and part of the side surface of the lower electrode layer 110c. The resistance conversion layer 116a covers the interface layers 112a, 112b and the lower electrode layer 110e, and has a U-shaped profile. The upper electrode layer 118a covers the resistance conversion layer 116a, and the lower electrode layer 110e surrounds the interface layers 112a, 112b, the resistance conversion layer 116a and the upper electrode layer 118a. In one embodiment, the lower electrode layer 110e, the resistance conversion layer 116a and the upper electrode layer 118a form a U-shaped structure, and the U-shaped structure is at the same height as the through hole 108, or the upper surface of the U-shaped structure is coplanar with the opening portion of the through hole 108. In FIG. 3, the interface layer includes a first interface layer 112a and a second interface layer 112b. The first interface layer 112a and the second interface layer 112b are coplanar at their top surface and cover the bottom surface of the lower electrode layer 110e and the area covered on the bottom surface is substantially the same as the bottom area of the lower electrode layer 110c. In FIG. 4, the interface layer includes a first interface layer 112a and a second interface layer 112b. The first interface layer 112a and the second interface layer 112b have a convex profile at their top surface and are disposed on the bottom surface of the lower electrode layer 110e, and the area covered on the bottom surface is smaller than the bottom area of the bottom electrode layer 110c. That is to say, in FIG. 4, the interface layers 112a and 112b do not cover the side surfaces of the lower electrode layer 110c. Therefore, the resistance conversion layer 116a extends downward from the edges of the interface layers 112a and 112b to the bottom surface of the lower electrode layer 110e, so as to cover and surround the first interface layer 112a and the second interface layer 112b between the resistance conversion layer 116a and the lower electrode layer 110c.

Similar to FIGS. 2C and 2D, partial etching back is performed on the first interface layer 112b and the second interface layer 112b to remove the portions not covered by the mask layer 114 and the side surfaces of the first interface layer 112a and the second interface layer 112b are over-etched to have flat surface at the top or even have a convex profile when the etchant reaches the bottom surface of the lower electrode layer 110e and the side surfaces thereof are etched completely, so that the first interface layer 112a and the second interface layer 112b have different profiles in FIGS. 3 and 4.

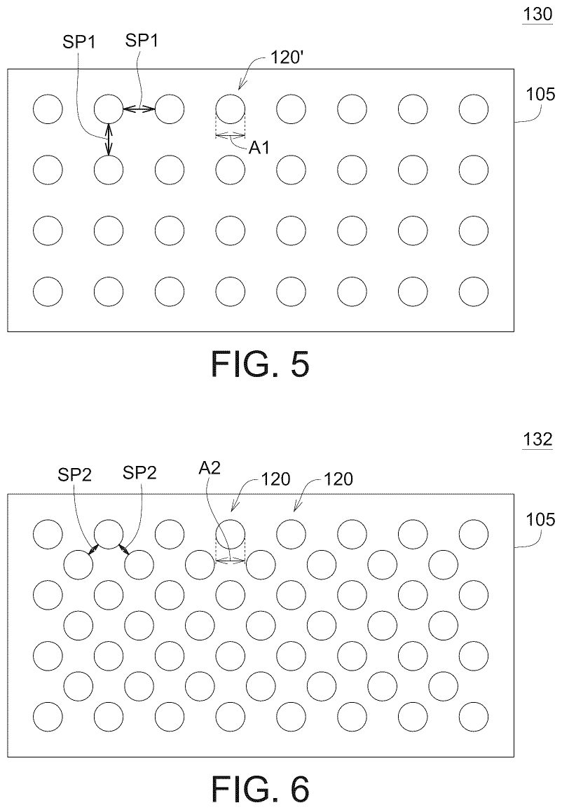

Referring to FIGS. 5 and 6, FIGS. 5 and 6 respectively are schematic diagrams of a planar RRAM structure 130 and an embedded RRAM structure 132. In FIGS. 5 and 6, an RRAM array is arranged in the same area. If a traditional planar RRAM structure 130 is applied, the spacing SP1 between adjacent resistive random access memories (RRAM) 120′ is large and each of RRAMs 120′ occupies a larger footprint A1, so the number of resistive random access memories (RRAM) 120′ formed in the same area is smaller. In FIG. 6, if an embedded RRAM structure 132 is applied, since the spacing SP2 between adjacent resistive random access memories (RRAM) 120 is smaller and each of RRAMs 120 occupies a smaller footprint A2, so the number of resistive random access memories (RRAM) 120 formed in the same area is more than the number of RRAM 120′. In one embodiment, the footprint ratio (A2/A1) of the embedded RRAM structure 132 compared to the traditional planar RRAM structure 130 can be reduced or equal, and the spacing ratio (SP2/SP1) of the embedded RRAM structure 130 compared to the traditional planar RRAM structure 130 can be reduced by about 1.5 to 2 times. The pitch SP2 of the embedded RRAM structure 132 can be about less than 20 nm or less than 10 nm, and the footprint A2 is approximately the opening area of the through hole 108. In addition, the embedded RRAM structure 132 can be configured in a circular, oval or rectangular shape, and its shape can be determined according to the opening shape of the through hole 108.

The present disclosure is directed to a resistive random access memory (RRAM) and a manufacturing method thereof. The chemical mechanical polishing (CMP) process or wet etching process for the resistive random access memory is performed to replace the dry etching press to avoid the sidewall of electrodes from plasma damage. The resistive random access memory (RRAM) is embedded in a through hole and includes a U-shaped lower electrode layer to shrink the size of memory structure, so that the formation speed of the conductive filaments in the resistance conversion layer will be increased, thereby increasing the programming speed of the resistive random access memory.

According to some embodiments of the present disclosure, a resistive random access memory includes the following steps. An interlayer dielectric layer is formed on a semiconductor substrate. A first conductive material layer is formed in a through hole of the interlayer dielectric layer. At least one interface layer is formed in the through hole. The interface layer covers a bottom surface of the first conductive material layer and exposes a side surface of the first conductive material layer. A resistive material layer is formed in the through hole, and the resistive material layer covers the interface layer and the side surface of the first conductive material layer. A second conductive material layer is formed in the through hole, and the second conductive material layer covers the resistive material layer. A planarization process is performed on the first conductive material layer, the resistive material layer and the second conductive material layer to form an embedded resistive random access memory in the through hole.

According to some embodiments of the present disclosure, a method of manufacturing a resistive random access memory includes the following steps. An interlayer dielectric layer is formed on a semiconductor substrate. A first conductive material layer, at least one interface layer, a resistive material layer and a second conductive material layer are sequentially formed in a through hole of the interlayer dielectric layer, wherein the first conductive material layer surrounds the interface layer, the resistive material layer and the second conductive material layer. A planarization process is performed on the first conductive material layer, the resistive material layer and the second conductive material layer to form an embedded resistive random access memory in the through hole.

According to some embodiments of the present disclosure, a resistive random access memory embedded in a through hole is provided, the resistive random access memory includes a lower electrode layer, at least one interface layer, a resistance conversion layer, and an upper electrode layer. The lower electrode layer is disposed in the through hole, and the lower electrode layer has a U-shaped profile. The at least one interface layer covers a bottom surface of the lower electrode layer. The resistance conversion layer covers the interface layer and the lower electrode layer, and the resistance conversion layer has a U-shaped profile. The upper electrode layer covers the resistance conversion layer, wherein the lower electrode layer surrounds the interface layer, the resistance conversion layer and the upper electrode layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a resistive random access memory, comprising:
forming an interlayer dielectric layer on a semiconductor substrate;
forming a first conductive material layer in a through hole of the interlayer dielectric layer;
forming at least one interface layer in the through hole, the interface layer covering a bottom surface of the first conductive material layer and exposing a portion of a side surface of the first conductive material layer;
forming a resistive material layer in the through hole, the resistive material layer covering the interface layer and the portion of the side surface of the first conductive material layer;
forming a second conductive material layer in the through hole, the second conductive material layer covering the resistive material layer; and
performing a planarization on the first conductive material layer, the resistive material layer and the second conductive material layer to form an embedded resistive random access memory in the through hole.

2. The method of claim 1, wherein an upper surface of the embedded resistive random access memory is coplanar with an upper surface of the interlayer dielectric layer.

3. The method of claim 1, wherein the first conductive material layer serves as a lower electrode layer of the embedded resistive random access memory, and the second conductive material layer serves as an upper electrode layer of the embedded resistive random access memory, the resistive material layer serves as a resistance conversion layer of the embedded resistive random access memory, wherein the lower electrode layer surrounds the interface layer, the resistance conversion layer and the upper electrode layer.

4. The method of claim 1, wherein topmost portions of the first conductive material layer, the resistive material layer and the second conductive material layer are coplanar with an upper surface of the interlayer dielectric layer.

5. The method of claim 1, wherein first conductive material layer has a U-shaped profile.

6. The method of claim 1, wherein the resistive material layer has a U-shaped profile.

7. The method of claim 1, wherein the interface layer includes a first interface layer and a second interface layer, and the first interface layer and the second interface layer cover a bottom surface and a portion of a side surface of the first conductive material layer.

8. The method of claim 1, wherein the interface layer includes a first interface layer and a second interface layer, and the first interface layer and the second interface layer cover a portion of a bottom surface of the first conductive material layer and do not cover a side surface of the first conductive material layer.

9. The method of claim 8, wherein the resistive material layer extends downward from an edge of the interface layer to the bottom surface of the first conductive material layer.

10. A method of manufacturing a resistive random access memory, comprising:
forming an interlayer dielectric layer on a semiconductor substrate;
sequentially forming a first conductive material layer, at least one interface layer, a resistive material layer and a second conductive material layer in a through hole of the interlayer dielectric layer, wherein the first conductive material layer surrounds the interface layer, the resistive material layer and the second conductive material layer;
etching the at least one interface layer to define a shape or a height of the at least one interface layer, and the height of the at least one interface layer is lower than a height of the first conductive material layer in the through hole;
defining shapes of the first conductive material layer, the resistive material layer to be U-shape in the through hole; and
performing a planarization on the first conductive material layer, the resistive material layer and the second conductive material layer to form an embedded resistive random access memory in the through hole.

11. The method of claim 10, wherein forming the interface layer includes etching back the interface layer so that the interface layer covers a bottom surface of the first conductive material layer and exposes a side surface of the first conductive material layer.

12. The method of claim 11, wherein the interface layer includes a first interface layer and a second interface layer, the first interface layer and the second interface layer cover the bottom surface and a portion of the side surface of the first conductive material layer.

13. The method of claim 11, wherein the interface layer includes a first interface layer and a second interface layer, and the first interface layer and the second interface layer cover a portion of the bottom surface of the first conductive material layer and do not cover the side surface of the first conductive material layer.

14. The method of claim 13, wherein the resistive material layer extends downward from an edge of the interface layer to the bottom surface of the first conductive material layer.

15. The method of claim 10, wherein the first conductive material layer, the resistive material layer and the second conductive material layer are chemically or mechanically polished to have a flat upper surface.

16. A resistive random access memory (RRAM) embedded in a through hole, the resistive random access memory comprising:
a lower electrode layer disposed in the through hole, and the lower electrode layer having a U-shaped profile;
at least one interface layer covering a bottom surface of the lower electrode layer;
a resistance conversion layer covering the interface layer and the lower electrode layer, the resistance conversion layer having a U-shaped profile; and
an upper electrode layer covers the resistance conversion layer, wherein the lower electrode layer surrounds the interface layer, the resistance conversion layer and the upper electrode layer.

17. The RRAM of claim 16, wherein topmost portions of the lower electrode layer, the resistance conversion layer and the upper electrode layer are coplanar.

18. The RRAM of claim 16, wherein the interface layer includes a first interface layer and a second interface layer, the first interface layer and the second interface layer cover the bottom surface and a portion of a side surface of the lower electrode layer.

19. The RRAM of claim 16, wherein the interface layer includes a first interface layer and a second interface layer, and the first interface layer and the second interface layer cover a portion of a bottom surface of the lower electrode layer and do not cover a side surface of the lower electrode layer.

20. The RRAM of claim 19, wherein the resistance conversion layer extends downward from an edge of the interface layer to the bottom surface of the lower electrode layer.
